(19) United States
(12) Patent Application Publication
(10) Pub. No.: US 2025/0063873 A1
(43) Pub. Date: Feb. 20, 2025

(54) MANUFACTURING METHOD OF ELECTRONIC DEVICE

(71) Applicant: InnoLux Corporation, Miao-Li County (TW)

(72) Inventor: Chen-Kuan KAO, Miao-Li County (TW)

(73) Assignee: InnoLux Corporation, Miao-Li County (TW)

(21) Appl. No.: 18/767,927

(22) Filed: Jul. 9, 2024

(30) Foreign Application Priority Data
Aug. 16, 2023 (CN) 202311029421.2

(51) Int. Cl. H01L 33/62; H01L 27/15

(52) U.S. Cl. CPC H01L 33/62; H01L 27/156; H01L 2933/0066

(57) ABSTRACT

A manufacturing method of an electronic device includes: providing a substrate; disposing a conductive layer on the substrate; performing a patterning step to pattern the conductive layer, such that a grid structure having a plurality of grid units is formed in the conductive layer, and the conductive layer which is patterned includes a first portion and a second portion at least; and performing an electroplating step to electroplate at least one of the first portion and the second portion, such that a thickness of the first portion is different from a thickness of the second portion after performing the electroplating step.

### BACKGROUND OF THE DISCLOSURE

### 1. Field of the Disclosure

The present disclosure relates to a manufacturing method of an electronic device, and more particularly to a manufacturing method capable of enhancing a display quality and a yield rate of an electronic device.

### 2. Description of the Prior Art

As the evolution and development of electronic devices, the electronic devices have become an indispensable item. For instance, the electronic device (e.g., the display panel or the display device) having a displaying function could provide convenient information transmission and/or image display. In order to make the electronic device (e.g., the display panel or the display device) have a good display quality and to enhance a yield rate of the electronic device, the industry is committed to developing a manufacturing method of this electronic device and/or a manufacturing method for disposing structures of this electronic device, thereby correspondingly improving existing display problems and manufacturing problems.

### SUMMARY OF THE DISCLOSURE

According to an embodiment, the present disclosure provides a manufacturing method of an electronic device. The manufacturing method includes: providing a substrate; disposing a conductive layer on the substrate; performing a patterning step to pattern the conductive layer, such that a grid structure having a plurality of grid units is formed in the conductive layer, and the conductive layer which is patterned includes a first portion and a second portion at least; and performing an electroplating step to electroplate at least one of the first portion and the second portion, such that a thickness of the first portion is different from a thickness of the second portion after performing the electroplating step.

According to an embodiment, the present disclosure further provides a manufacturing method of an electronic device. The manufacturing method includes: providing a substrate; and performing an inkjet printing step to form a conductive layer on the substrate. The conductive layer includes a grid structure having a plurality of grid units, the conductive layer includes a first portion and a second portion at least, and a thickness of the first portion is different from a thickness of the second portion.

### BRIEF DESCRIPTION OF THE DRAWINGS

FIG. 1 is a schematic diagram showing a cross-sectional view of a display unit of an electronic device according to an embodiment of the present disclosure.

FIG. 2 is a schematic diagram showing a top view of a display unit of an electronic device according to an embodiment of the present disclosure.

FIG. 3 is a schematic diagram showing a top view of a grid structure of a conductive layer of an electronic device according to an embodiment of the present disclosure.

FIG. 4 is a schematic diagram showing a top view of a grid structure of a conductive layer of an electronic device according to another embodiment of the present disclosure.

FIG. 5 to FIG. 7 are schematic diagrams illustrating structures at different stages of a manufacturing method of an electronic device according to a first embodiment of the present disclosure.

FIG. 8 is a schematic diagram showing a relation between an electric current density and a metal growth rate in an electroplating step of the manufacturing method of the electronic device according to the first embodiment of the present disclosure.

FIG. 9 to FIG. 13 are schematic diagrams s illustrating structures at different stages of a manufacturing method of an electronic device according to a second embodiment of the present disclosure.

FIG. 14 to FIG. 15 are schematic diagrams illustrating structures at different stages of a manufacturing method of an electronic device according to a third embodiment of the present disclosure.

FIG. 16 to FIG. 18 are schematic diagrams illustrating structures at different stages of a manufacturing method of an electronic device according to a fourth embodiment of the present disclosure.

FIG. 19 to FIG. 23 are schematic diagrams illustrating structures at different stages of a manufacturing method of an electronic device according to a fifth embodiment of the present disclosure.

FIG. 24 to FIG. 25 are schematic diagrams illustrating structures at different stages of a manufacturing method of an electronic device according to a sixth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the corresponding component and the another component have a disposition relationship along a top-view/vertical direction, the corresponding component may be below or above the another component, and the disposition relationship along the top-view/vertical direction are determined by an orientation of the device.

When a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction, and the term “cross-sectional view” generally means a viewing result viewing a structure cutting along the vertical direction along the horizontal direction.

In the description and following claims, it should be noted that the term “overlap” means that two elements overlap along the direction Z, and the term “overlap” can be “partially overlap” or “completely overlap” in unspecified circumstances.

In the description and following claims, the term “thickness” generally means a maximum distance between two opposite surfaces of an element in the direction Z, and the thickness of this element is measured by any suitable method. For instance, the thickness of this element may be measured through a microscope (e.g., an optical microscope, a scanning electron microscope (SEM), etc.).

The terms “about”, “approximately”, “substantially”, “equal”, or “same” generally mean within ±10% of a given value or range, or mean within ±5%, ±3%, ±2%, ±1%, or ±0.5% of a given value or range.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

In the present disclosure, the electronic device may be a non-self-luminous type display panel or a self-luminous type display panel based on requirement(s), and the electronic device may be a color display panel or a monochrome display panel based on requirement(s). In the present disclosure, electronic components in the electronic device may include passive component(s) and active component(s), such as capacitor(s), resistor(s), inductor(s), diode(s), transistor(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device. In the present disclosure, the display panel may be included in the electronic device, and this electronic device may further include a lighting device, an antenna device, a sensing device, a tiled device or a combination thereof, but not limited thereto. The antenna device may be a liquid-crystal-type antenna device or a non-liquid-crystal-type antenna device, the sensing device may be a device for sensing capacitance, light, thermal or ultrasonic, and the tiled device may be a tiled display panel or a tiled antenna device, but not limited thereto.

For example, the electronic device is a non-self-luminous type color display panel in the following, but not limited thereto.

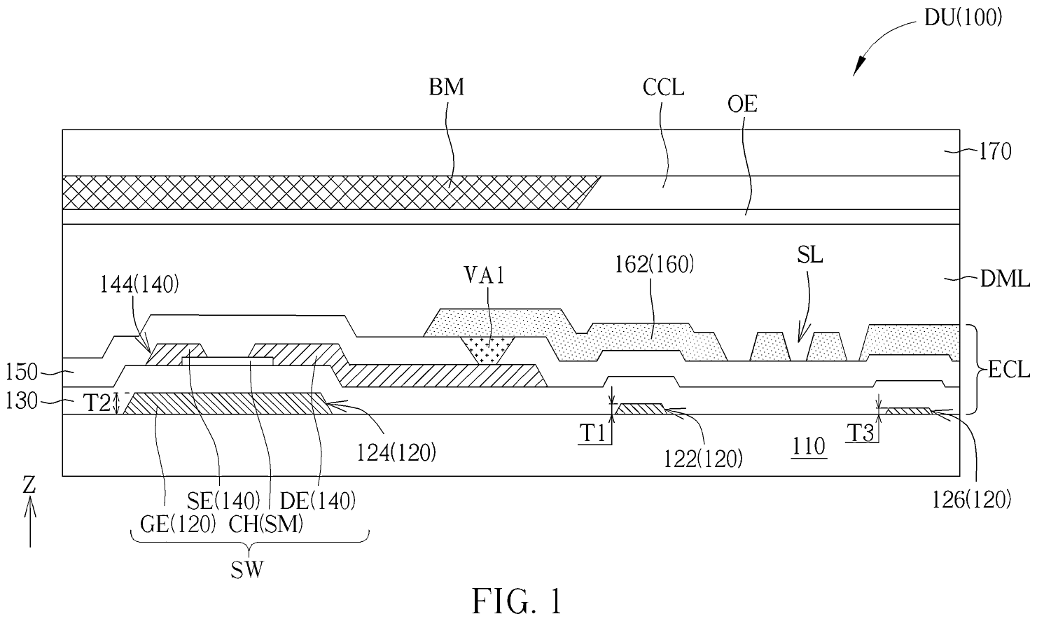

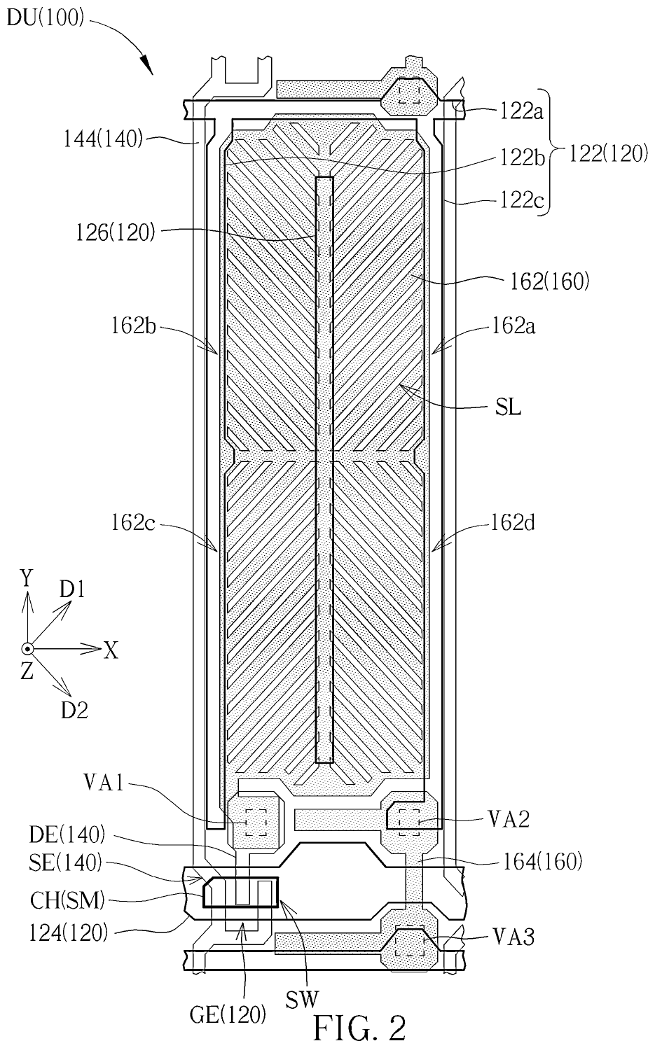

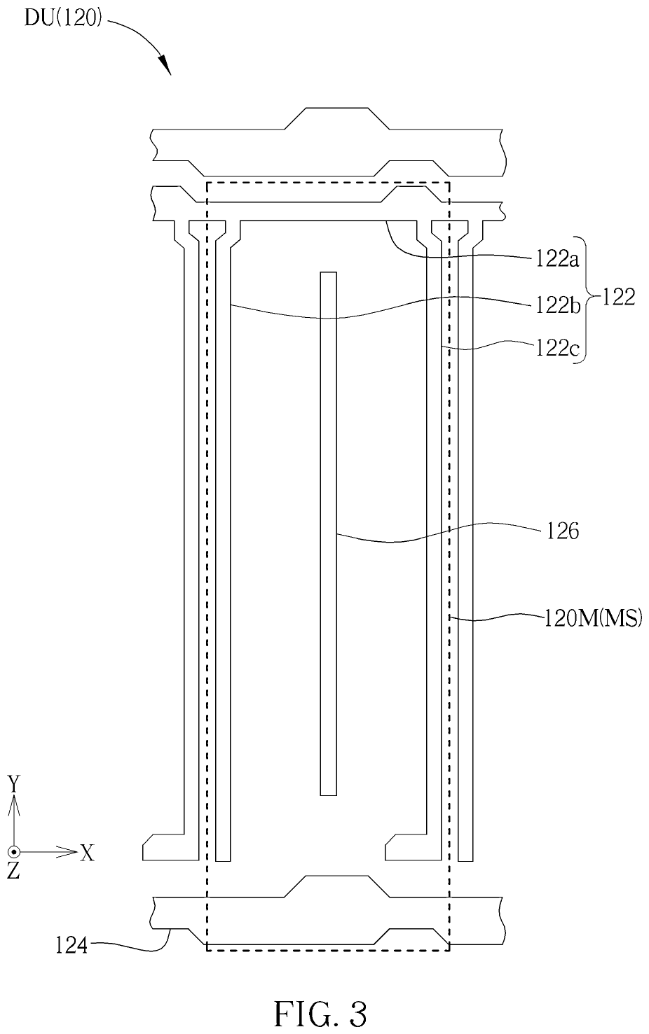

Referring to FIG. 1 to FIG. 3, FIG. 1 is a schematic diagram showing a cross-sectional view of a display unit of an electronic device according to an embodiment of the present disclosure, FIG. 2 is a schematic diagram showing a top view of a display unit of an electronic device according to an embodiment of the present disclosure, and FIG. 3 is a schematic diagram showing a top view of a grid structure of a conductive layer of an electronic device according to an embodiment of the present disclosure. As shown in FIG. 1 and FIG. 2, the electronic device 100 may include a plurality of display units DU, wherein the display unit DU may serve as a smallest unit of a displaying image. For example, the display unit DU may be a sub-pixel displaying one color, but not limited thereto. In this embodiment, since the electronic device 100 is a color display panel, several display units DU may form a display group (or referred as a pixel), wherein the display units DU of this display group may be corresponding to different colors, and the number and the colors of the display units DU included in this display group may be adjusted based on requirement(s) (e.g., one display group may include a green display unit, a red display unit and a blue display unit). In another embodiment, when the electronic device 100 is a monochrome display panel, the display units DU may be corresponding to the same color.

In the present disclosure, the number, the arrangement and the shape of the display units DU may be adjusted based on requirement(s). For example, in FIG. 2, the display units DU may be rectangular substantially, and the display units DU may be arranged in the direction X and the direction Y to form an array, but not limited thereto.

As shown in FIG. 1 and FIG. 2, the electronic device 100 may include a substrate 110, and the electronic device 100 may optionally include an opposite substrate 170, wherein the substrate 110 and the opposite substrate 170 may be rigid or flexible individually. Based on the type of the substrate 110 and the type of the opposite substrate 170, the substrate 110 and the opposite substrate 170 may individually include glass, quartz, ceramic, sapphire, polymer (e.g., polyimide (PI), polyethylene terephthalate (PET), etc.), other suitable materials or a combination thereof. In some embodiments, structures and components included in the display unit DU may be disposed on the substrate 110 and/or be disposed between the substrate 110 and the opposite substrate 170. Note that a normal direction of the substrate 110 and a normal direction of the opposite substrate 170 may be parallel to the direction Z.

As shown in FIG. 1, since the electronic device 100 is a non-self-luminous type display panel, the electronic device 100 may include a display medium layer DML disposed between the substrate 110 and the opposite substrate 170. The display medium layer DML may include any suitable material according to the type of the electronic device 100. For instance, the display medium layer DML includes liquid crystal molecules or other suitable display medium material, but not limited thereto. The display medium material included in the display medium layer DML may be adjusted by any suitable method, so as to adjust the status of a part of the display medium layer DML corresponding to the display unit DU, thereby adjusting the light transmittance of this display unit DU. For instance, in some embodiments, the status of the display medium layer DML may be controlled by an electric field and/or at least one electrical signal.

In the present disclosure, electrode(s) configured to control the status of the display medium layer DML may be designed based on requirement(s). For instance, a plurality of electrodes configured to control the display medium layer DML may be disposed on opposite sides of the display medium layer DML (i.e., one electrode may be disposed between the display medium layer DML and the substrate 110, and another electrode may be disposed between the display medium layer DML and the opposite substrate 170, such that the display medium layer DML may be disposed between these electrodes), but not limited thereto. For instance, a plurality of electrodes configured to control the display medium layer DML may be disposed on the same side of the display medium layer DML, but not limited thereto. In some embodiments, each display unit DU may include at least two electrodes configured to control the display medium layer DML, so as to make the status of a part of the display medium material of the display medium layer DML corresponding to the display unit DU be adjusted according to the electrical signals (e.g., a gray level signal) received by the electrodes, thereby adjusting the light transmittance of the display unit DU. For example, in the following, two electrodes configured to control the status of the display medium layer DML may be disposed on opposite sides of the display medium layer DML, but not limited thereto.

As shown in FIG. 1 and FIG. 2, a circuit component layer ECL may be disposed on the substrate 110 and exist between the substrate 110 and the display medium layer DML. The circuit component layer ECL may include at least one conductive layer, at least one insulating layer, at least one semiconductor layer or a combination thereof, so as to form electronic components (e.g., electronic components of the display unit DU) in the circuit component layer ECL. The material of the conductive layer may include such as metal, transparent conductive material (such as indium tin oxide (ITO), indium zinc oxide (IZO), etc.), other suitable conductive material(s) or a combination thereof, but not limited thereto. The material of the insulating layer may include such as silicon oxide (SiOₓ), silicon nitride (SiN_{y}), silicon oxynitride (SiOₓN_{y}), organic insulating material (e.g., photosensitive resin), other suitable insulating material(s) or a combination thereof, but not limited thereto. The material of the semiconductor layer may include such as poly-silicon, amorphous silicon, metal-oxide semiconductor, other suitable semiconductor material(s) or a combination thereof, but not limited thereto. The conductive layer may be a single-layer structure or a multi-layer structure based on requirement(s), and the insulating layer may be a single-layer structure or a multi-layer structure based on requirement(s). For example, in FIG. 1 and FIG. 2, the circuit component layer ECL may include a conductive layer 120, a first insulating layer 130, a semiconductor layer SM, a conductive layer 140, a second insulating layer 150 and a conductive layer 160 disposed on the substrate 110 in sequence, wherein the conductive layer 120 may include at least one metal layer, the conductive layer 140 may include at least one metal layer, and the conductive layer 160 may be a transparent conductive layer, but not limited thereto.

The circuit component layer ECL may include any suitable electronic component, and the electronic component may be formed of the aforementioned layer(s) in the circuit component layer ECL. In FIG. 1 and FIG. 2, the circuit component layer ECL may include at least one switching component SW disposed in the display unit DU, wherein the switching component SW may be a top gate thin film transistor, a bottom gate thin film transistor, a dual gate thin film transistor or other suitable switching component (the switching component SW shown in FIG. 1 and FIG. 2 is a bottom gate thin film transistor for example). For instance, the conductive layer 120 may include a gate GE of the switching component SW, the first insulating layer 130 may include a gate insulating layer of the switching component SW, the semiconductor layer SM may include a channel layer CH of the switching component SW, and the conductive layer 140 may include a source SE and a drain DE of the switching component SW, but not limited thereto. Although FIG. 1 and FIG. 2 only show one switching component SW in the display unit DU, the number of the switching component(s) SW in the display unit DU may be designed based on requirement(s).

In FIG. 1 to FIG. 3, the circuit component layer ECL may further include at least one scan line 124 and at least one data line 144, wherein the scan line 124 may be configured to transmit a switching signal for turning on or turning off the switching component SW, and the data line 144 may be configured to transmit the electrical signal (e.g., the gray level signal) related to the status of the displaying image. For instance, the scan line 124 may be electrically connected to the gate GE of the switching component SW, and the data line 144 may be electrically connected to the source SE of the switching component SW, but not limited thereto. In the present disclosure, the conductive layer 120 may include the scan line 124 (i.e., the scan line 124 and the gate GE may belong to the same layer), and the conductive layer 140 may include the data line 144 (i.e., the data line 144 and the source SE may belong to the same layer). Thus, in FIG. 1 to FIG. 3, a part of the scan line 124 and a part of the data line 144 may be disposed in the display unit DU. Moreover, in FIG. 1 to FIG. 3, the scan line 124 may be (substantially) parallel to the direction X to pass through at least two display units DU in the direction X, the data line 144 may be (substantially) parallel to the direction Y to pass through at least two display units DU in the direction Y, but not limited thereto.

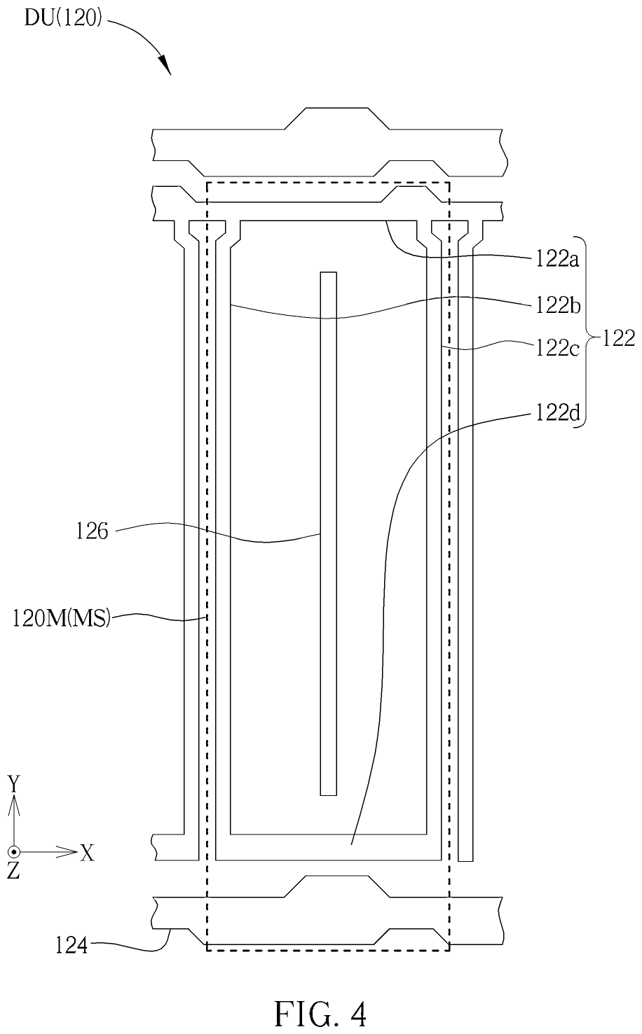

In the present disclosure, the conductive layer 120 of the circuit component layer ECL may further include a common level structure 122 configured to receive a common voltage or to ground, wherein at least a part of the common level structure 122 may be disposed in the display unit DU, and the common level structure 122 and the scan line 124 may be separated from each other and not be electrically connected to each other. In the present disclosure, the common level structure 122 may have any suitable pattern based on requirement(s). For example, in FIG. 1 to FIG. 3, the common level structure 122 may include a first sub-part 122a, a second sub-part 122b and a third sub-part 122c, the first sub-part 122a may be directly connected to the second sub-part 122b and the third sub-part 122c, the first sub-part 122a may be (substantially) parallel to the direction X, and the second sub-part 122b and the third sub-part 122c may be (substantially) parallel to the direction Y and opposite to each other in the direction X, such that the common level structure 122 may have a U-shaped pattern, but not limited thereto. For example, in FIG. 4, the common level structure 122 may include a first sub-part 122a, a second sub-part 122b, a third sub-part 122c and a fourth sub-part 122d, the first sub-part 122a and the fourth sub-part 122d may be directly connected to the second sub-part 122b and the third sub-part 122c, the first sub-part 122a and the fourth sub-part 122d may be (substantially) parallel to the direction X and opposite to each other in the direction Y, and the second sub-part 122b and the third sub-part 122c may be (substantially) parallel to the direction Y and opposite to each other in the direction X, such that the common level structure 122 may have a closed shape (e.g., a rectangular-like ring shape), but not limited thereto. In some embodiments, the common level structure 122 may overlap or be closed to at least one edge of the display unit DU, but not limited thereto. For example, in FIG. 1 to FIG. 4, the common level structure 122 may overlap three edges of the display unit DU, and the scan line 124 may overlap or be closed to another edge of the display unit DU, but not limited thereto.

As shown in FIG. 1 to FIG. 4, the common level structures 122 in different display units DU may be electrically connected to each other. For instance, in FIG. 1 to FIG. 4, the common level structures 122 in two adjacent display units DU in the direction X may be electrically connected to each other through the first sub-parts 122a of these common level structures 122, but not limited thereto. For instance, in FIG. 1 to FIG. 4, in two adjacent display units DU in the direction Y, the third sub-part 122c (or the fourth sub-part 122d) of one common level structure 122 may be electrically connected to the first sub-part 122a of another common level structure 122 through a conductive structure belonging to other film(s) (e.g., a common connecting structure 164 of the conductive layer 160 may cross over the scan line 124 and be electrically connected between two common level structures 122), but not limited thereto.

According to FIG. 1 to FIG. 4, the common level structure 122 and the scan line 124 formed by performing a patterning step on the conductive layer 120 of the circuit component layer ECL may form a mesh-like grid structure MS, wherein the grid structure MS may include a plurality of grid units 120M, and one display unit DU may be corresponding to one grid unit 120M (e.g., the electronic components in one display unit DU may be disposed a region surrounded by one grid unit 120M). For instance, in FIG. 1 to FIG. 3, the common level structure 122 and the scan line 124 may form the grid unit 120M with a rectangular-like ring shape in the top view (since the common level structure 122 and the scan line 124 may be separated from each other, the grid unit 120M shown in FIG. 1 to FIG. 3 may be composed of these two separate components), wherein the common level structure 122 may include three edges of the grid unit 120M, and the scan line 124 may include one edge of the grid unit 120M, but not limited thereto. For instance, in FIG. 4, the common level structure 122 may form the grid unit 120M with a rectangular-like ring shape in the top view, wherein the common level structure 122 may include four edges (i.e., all edges) of the grid unit 120M, but not limited thereto. According to above, the common level structure 122 may include at least one edge of the grid unit 120M.

In another aspect, in FIG. 1 to FIG. 4, since a plurality of common level structures 122 may be adjacent to and/or connected to each other (e.g., two adjacent common level structures 122 in the direction X may be connected to each other through the first sub-parts 122a, and two adjacent common level structures 122 in the direction Y may be adjacent to each other), these grid units 120M may form the grid structure MS (i.e., the conductive layer 120 may include the grid structure MS having a plurality of grid units 120M). In addition, since the common level structures 122 of two adjacent display units DU in the direction X may be arranged in the direction X, and the scan line 124 may pass through at least two display units DU in the direction X, the scan line 124 may be corresponding to at least two grid units 120M (e.g., the scan line 124 shown in FIG. 3 may include a part corresponding to the grid unit 120M, and the scan line 124 shown in FIG. 4 may be adjacent to the corresponding grid unit 120M in the direction Y). For stance, the scan line 124 may be corresponding to the grid units 120M arranged in a row extending along the direction X, but not limited thereto.

In FIG. 1 and FIG. 2, the conductive layer 160 of the circuit component layer ECL may include a pixel electrode 162 disposed in the display unit DU, wherein the pixel electrode 162 may be configured to receive the gray level signal to control the status of the display medium layer DML, such that the display unit DU may provide the light with the corresponding light intensity according to the gray level signal received by its pixel electrode 162, thereby making the electronic device 100 display an image. In FIG. 1 and FIG. 2, the pixel electrode 162 may be electrically connected to the drain DE of the switching component SW, so as to receive the gray level signal, but not limited thereto. In FIG. 1 and FIG. 2, the pixel electrode 162 may include a plurality of slits SL, so as to improve the control effect of the pixel electrode 162 on the status of the display medium layer DML, thereby enhancing the display quality of the electronic device 100. For instance, in FIG. 2, the pixel electrode 162 may have four regions 162a, 162b, 162c and 162d arranged in a 2×2 array, the slits SL in the region 162a and the region 162c may extend along a direction D1, and the slits SL in the region 162b and the region 162d may extend along a direction D2, wherein the direction D1 and the direction D2 may not be parallel to each other, the direction D1 and the direction D2 may be perpendicular to the direction Z, and the direction D1 and the direction D2 may not be parallel to the direction X and the direction Y, but not limited thereto. Moreover, in some embodiments, the edge(s) of the pixel electrode 162 may partially overlap the common level structure 122, so as to decrease the light leakage, but not limited thereto.

Optionally, in FIG. 1 to FIG. 3, the circuit component layer ECL may further include a floating structure 126 disposed in the display unit DU, so as to improve the display quality of the electronic device 100 (e.g., the side-viewing display quality of the electronic device 100), wherein the floating structure 126 may not electrically connected to any electronic component, so as to be floating. For instance, in FIG. 1 to FIG. 3, the floating structure 126 may be a strip structure extending along the direction Y, and the floating structure 126 may be disposed between the region 162a and the region 162b of the pixel electrode 162 and be disposed between the region 162c and the region 162d of the pixel electrode 162 in the top view, so as to decrease the light leakage and enhance the contrast of the displaying image, but not limited thereto. For example, in FIG. 1 to FIG. 3, the floating structure 126 may be included in the conductive layer 120 and not be electrically connected to the common level structure 122 and the scan line 124, wherein the floating structure 126 may be disposed between the second sub-part 122b and the third sub-part 122c of the common level structure 122 in the top view, but not limited thereto.

According to above, as shown in FIG. 1, the conductive layer 120 may include the scan line 124, the common level structure 122 and the floating structure 126, such that the scan line 124, the common level structure 122 and the floating structure 126 belong to the same conductive layer.

In the present disclosure, the circuit component layer ECL may further include other suitable structure(s) based on requirement(s). For instance, in FIG. 1 and FIG. 2, the circuit component layer ECL may further include a conductive connecting structure disposed in a connecting hole of the insulating layer, so as to be connected between the conductive layers of the circuit component layer ECL. In FIG. 1 and FIG. 2, the pixel electrode 162 may be electrically connected to the drain DE of the switching component SW through the conductive connecting structure VA1, and the common connecting structure 164 may be respectively electrically connected to the third sub-part 122c (or the fourth sub-part 122d shown in FIG. 4) of one common level structure 122 and the first sub-part 122a of another common level structure 122 through the conductive connecting structures VA2 and VA3, but not limited thereto.

In FIG. 1, the electronic device 100 may further include an opposite electrode OE disposed between the opposite substrate 170 and the display medium layer DML, wherein the opposite electrode OE may be transparent and include transparent conductive material (e.g., ITO, IZO, etc.). In some embodiments, the electric field caused by the opposite electrode OE and the pixel electrode 162 may be configured to adjust the status of the display medium layer DML. For example, the opposite electrode OE may receive a common voltage, but not limited thereto.

In the present disclosure, the electronic device 100 may further include other suitable layer(s), component(s) and/or structure(s) based on requirement(s). In some embodiments, if the electronic device 100 is a color display panel, the electronic device 100 may further include a color conversion layer CCL disposed between the substrate 110 and the opposite substrate 170, so as to convert (or filter) the light (e.g., the white light) into another light with different color. The color conversion layer CCL may include color filter, quantum dots (QD) material, fluorescence material, phosphorescence material, other suitable material(s) or a combination thereof, but not limited thereto. As shown in FIG. 1, the color conversion layer CCL may be disposed between the display medium layer DML and the opposite substrate 170. In another embodiment, the color conversion layer CCL may be disposed above the opposite substrate 170, such that the opposite substrate 170 may be between the display medium layer DML and the color conversion layer CCL. In another embodiment, the color conversion layer CCL and the circuit component layer ECL may be disposed between the display medium layer DML and the substrate 110.

In some embodiments, the electronic device 100 may further include a light shielding layer BM having a light-shielding effect, so as to shield some regions with poor display effect, thereby enhancing the display quality of the electronic device 100. For example, the light shielding layer BM may include black photoresist, black ink, black resin, black pigment, other suitable material(s) or a combination thereof. The light shielding layer BM and the color conversion layer CCL may be disposed on the same layer; namely, top surfaces of the light shielding layer BM and the color conversion layer CCL or bottom surfaces of the light shielding layer BM and the color conversion layer CCL may be in contact with the same layer (e.g., the opposite substrate 170 and/or the opposite electrode OE), wherein the position of the light shielding layer BM may be changed together with the position of the color conversion layer CCL. For instance, in FIG. 1, the light shielding layer BM may be disposed between the display medium layer DML and the opposite substrate 170, but not limited thereto. In some embodiments, the light shielding layer BM may have a plurality of openings configured to define lighting regions of the display units DU and separate the display units DU from each other in the top view.

As shown in FIG. 1, the present disclosure makes the structures in the conductive layer 120 have different thicknesses through the manufacturing process design. In some embodiments, as shown in FIG. 1, the common level structure 122 may have a first thickness T1, the scan line 124 may have a second thickness T2, the floating structure 126 may have a third thickness T3, and the first thickness T1, the second thickness T2 and the third thickness T3 are different. In some embodiments, since the scan line 124 needs to have a low impedance characteristic, and the floating structure 126 has no electrical requirements, the second thickness T2 of the scan line 124 may be greater than the first thickness T1 of the common level structure 122, and the first thickness T1 of the common level structure 122 may be greater than the third thickness T3 of the floating structure 126. For example, the first thickness T1 of the common level structure 122 may range from 600 Å to 2500 Å (600 Å≤T1≤2500 Å), the second thickness T2 of the scan line 124 may be greater than or equal to 6000 Å (T2≥6000 Å) or range from 6000 Å to 9000 Å (6000 Å≤T2≤9000 Å), and the third thickness T3 of the floating structure 126 may range from 200 Å to 400 Å (200 Å≤T3≤400 Å), but not limited thereto. Accordingly, the common level structure 122, the scan line 124 and the floating structure 126 respectively have the thicknesses corresponding to their electrical requirements.

There may be manufacturing errors (e.g., an alignment error, an offset of a layer, etc.) during the manufacturing process of the electronic device 100. Since the edges of the structure of the conductive layer generally have chamfers (as shown in FIG. 1, the edges of the structure of the conductive layer are inclined planes), if the thickness of the conductive layer becomes greater, the influence caused by the conductive layer on the display medium material of the display medium layer DML becomes greater also, such that the display quality is decreased as the thickness of the conductive layer becomes greater (e.g., it makes the tilt angle of the liquid crystal molecules become greater to increase the light leakage). For example, when the manufacturing error is generated, the degree of the mura of the displaying image is increased as the thickness of the conductive layer becomes greater. In the present disclosure, since some structures of the conductive layer 120 have a thinner thickness, even if the manufacturing error occurs during the manufacturing process of the electronic device 100, the design of the present disclosure may reduce the light leakage caused by the conductive layer 120 and/or reduce the influence caused by the conductive layer 120 on the display medium material of the display medium layer DML, thereby enhancing the display quality (i.e., the mura is reduced).

On the other hand, since the edges of the structure of the conductive layer generally have chamfers, if the thickness of the conductive layer becomes greater, an area of a top surface (i.e., a horizontal surface) of the conductive layer is decreased, such that the contact area between the photoresist layer used in the subsequent process(es) and the top surface of the conductive layer is reduced, thereby causing the photoresist layer to be easily peeled off from the conductive layer to make the yield rate of the electronic device decreased. In the present disclosure, since some structures of the conductive layer 120 have a thinner thickness, the contact areas between the photoresist layer and the top surfaces of these structures are enhanced, thereby decreasing the peeling possibility of the photoresist layer to enhance the yield rate of the electronic device 100.

Furthermore, as shown in FIG. 1, in the present disclosure, since some structures of the conductive layer 120 have a thinner thickness, a distance between the conductive layers (e.g., the conductive layer 160 and the opposite electrode OE) disposed on opposite sides of the display medium layer DML is enhanced, so as to reduce the probability of damage due to short circuit between these two conductive layers (e.g., the short circuit may be caused by a conductive path formed between these two conductive layers during the manufacturing process), thereby enhancing the yield rate of the electronic device 100.

The manufacturing method of the electronic device 100 is described in the following, wherein the manufacturing method of the present disclosure is not limited to the following and the drawings. In some embodiments, any other suitable step may be added before or after one of the existing steps of the manufacturing method, and/or some steps may be performed simultaneously or separately.

In the following manufacturing method, the forming process of the layer and/or the structure may include an atomic layer deposition (ALD), a chemical vapor deposition (CVD), a coating process, any other suitable process or a combination thereof. The patterning process may include such as a photolithography, an etching process, any other suitable process or a combination thereof, wherein the etching process may be a wet etching process, a dry etching process, any other suitable etching process or combination thereof.

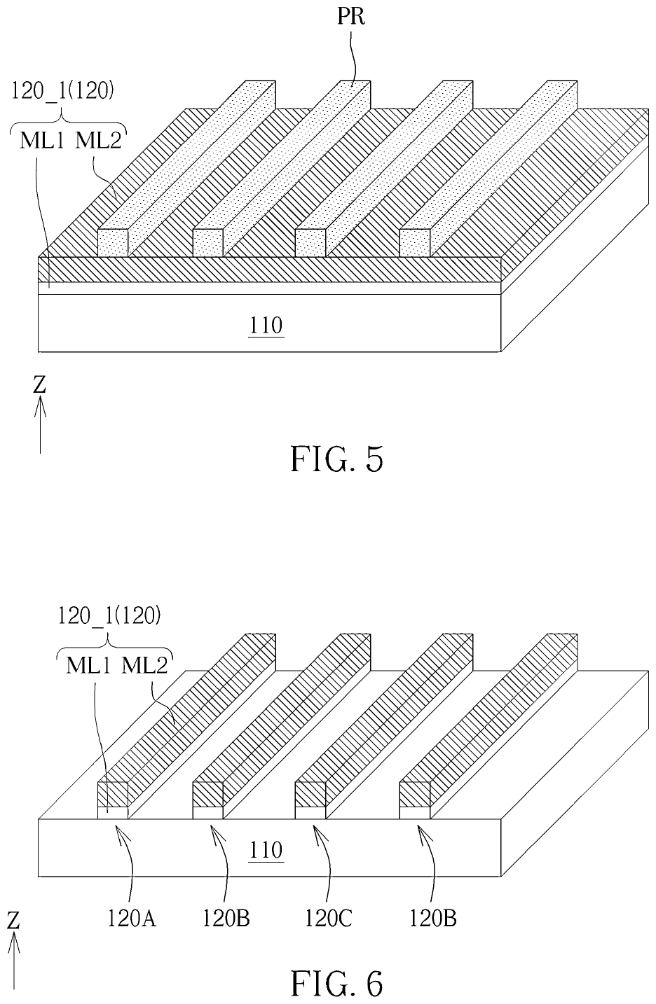

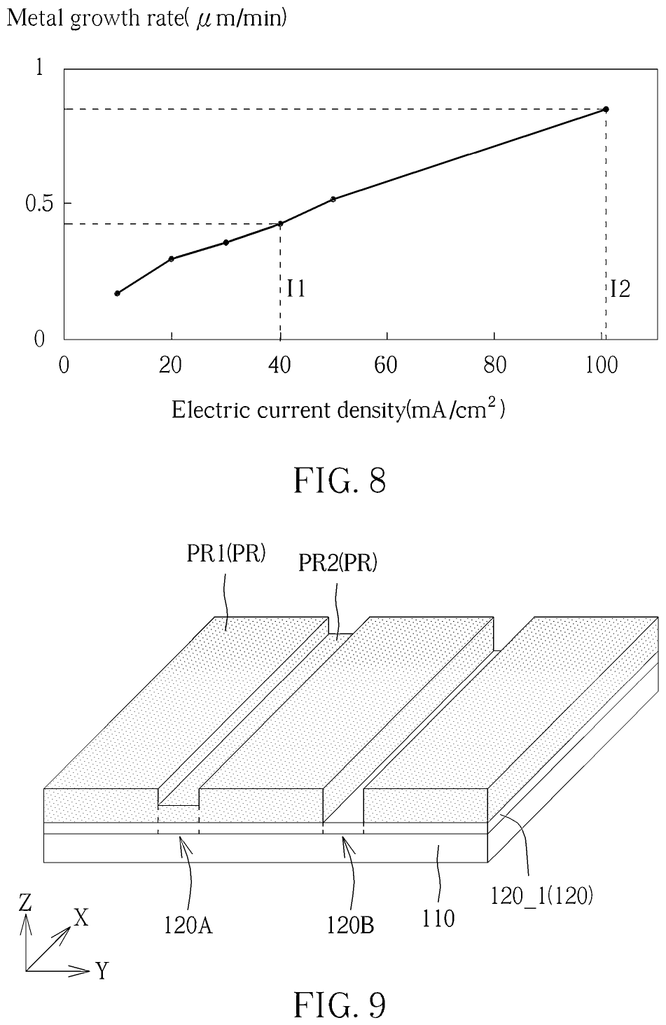

Referring to FIG. 5 to FIG. 8, FIG. 5 to FIG. 7 are schematic diagrams illustrating structures at different stages of a manufacturing method of an electronic device according to a first embodiment of the present disclosure, and FIG. 8 is a schematic diagram showing a relation between an electric current density and a metal growth rate in an electroplating step of the manufacturing method of the electronic device according to the first embodiment of the present disclosure. In the manufacturing method of the electronic device 100, as shown in FIG. 5, the substrate 110 is provided, and a first conductive sub-layer 120_1 belonging to the conductive layer 120 is formed on the substrate 110. The first conductive sub-layer 120_1 may include metal (e.g., molybdenum (Mo), aluminum (Al) and/or copper (Cu)), transparent conductive material (e.g., ITO), other suitable conductive material(s) or a combination thereof, and the first conductive sub-layer 120_1 may be a single-layer structure or a multi-layer structure based on requirement(s). For instance, in FIG. 5, the first conductive sub-layer 120_1 may be a multi-layer structure having a metal layer ML1 (e.g., molybdenum) and a metal layer ML2 (e.g., aluminum or copper), but not limited thereto.

As shown in FIG. 5 and FIG. 6, a patterning step (e.g., the photolithography) is performed to pattern the first conductive sub-layer 120_1, such that the first conductive sub-layer 120_1 (i.e., the conductive layer 120) includes a first portion 120A, a second portion 120B and a third portion 120C. The subsequent processes correspondingly make the first portion 120A to be the common level structure 122, correspondingly make the second portion 120B to be the scan line 124, and correspondingly make the third portion 120C to be the floating structure 126. After performing the patterning step, the first conductive sub-layer 120_1 (i.e., the conductive layer 120) includes the grid structure MS having a plurality of grid units 120M (these contents could be referred to the above).

In detail, in FIG. 5, a photoresist layer PR is formed on the first conductive sub-layer 120_1. Then, the photoresist layer PR is patterned by the yellow light manufacturing process and the developing process. Next, as shown in FIG. 6, the etching process is performed on the first conductive sub-layer 120_1, and the photoresist layer PR is removed, so as to complete the patterning step performed on the first conductive sub-layer 120_1.

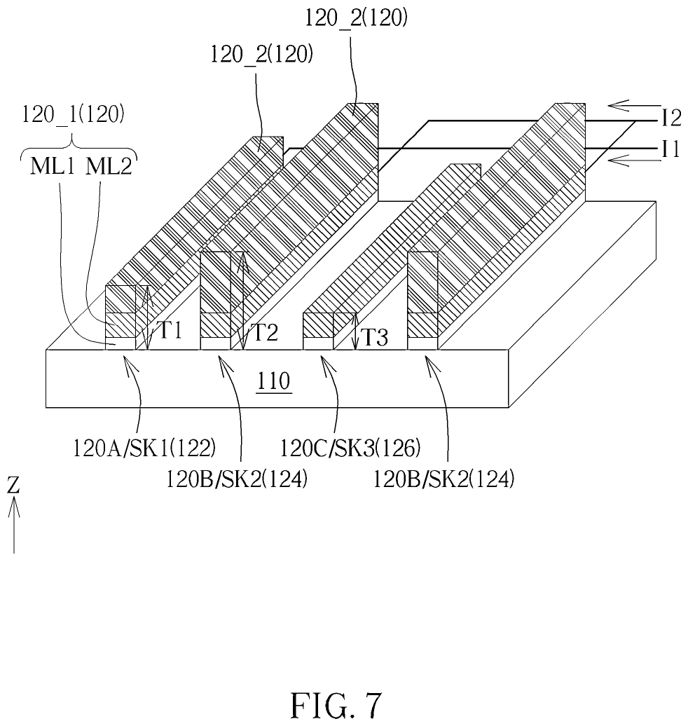

As shown in FIG. 7 and FIG. 8, an electroplating step is performed to energize the first conductive sub-layer 120_1, so as to electroplate at least one of the first portion 120A, the second portion 120B and the third portion 120C, such that the thickness of the first portion 120A, the thickness of the second portion 120B and the thickness of the third portion 120C are different after performing the electroplating step, thereby forming the common level structure 122, the scan line 124 and the floating structure 126 respectively having different thicknesses. For instance, in the electroplating step shown in FIG. 7, the first portion 120A and the second portion 120B are energized (i.e., the first portion 120A and the second portion 120B are coupled to an outer device providing electric currents), and the third portion 120C is not energized, so as to make a second conductive sub-layer 120_2 belonging to the conductive layer 120 be formed on the first portion 120A and the second portion 120B and not be formed on the third portion 120C; namely, in FIG. 7, the first portion 120A (i.e., the common level structure 122) and the second portion 120B (i.e., the scan line 124) of the conductive layer 120 are stacked structures stacked by the first conductive sub-layer 120_1 and the second conductive sub-layer 120_2, and the third portion 120C (i.e., the floating structure 126) of the conductive layer 120 is a structure formed of the first conductive sub-layer 120_1, but not limited thereto. Note that the second conductive sub-layer 120_2 may be a metal layer including any suitable metal (e.g., aluminum or copper).

In FIG. 7 and FIG. 8, in the electroplating step, the first portion 120A may be coupled to a first electric current I1, the second portion 120B may be coupled to a second electric current I2, and the first electric current I1 and the second electric current I2 may have different electric densities current (or electric current intensities), such that a metal growth rate of the first portion 120A and a metal growth rate of the second portion 120B may be different in the electroplating step (i.e., the second conductive sub-layer 120_2 may be formed at different speeds on the first portion 120A and the second portion 120B), so as to make a thickness of the second conductive sub-layer 120_2 on the first portion 120A different from a thickness of the second conductive sub-layer 120_2 on the second portion 120B, thereby making the first portion 120A (i.e., the common level structure 122) and the second portion 120B (i.e., the scan line 124) have different thickness after performing the electroplating step. In FIG. 7 and FIG. 8, the electric current density (or the electric current intensity) of the second electric current I2 may be greater than the electric current density (or the electric current intensity) of the first electric current I1, such that the second thickness T2 of the second portion 120B (i.e., the scan line 124) may be greater than the first thickness T1 of the first portion 120A (i.e., the common level structure 122). Furthermore, since the third portion 120C (i.e., the floating structure 126) does not have the second conductive sub-layer 120_2, the second thickness T2 of the second portion 120B (i.e., the scan line 124) and the first thickness T1 of the first portion 120A (i.e., the common level structure 122) are greater than the third thickness T3 of the third portion 120C (i.e., the floating structure 126).

In some embodiments (as shown in FIG. 7), the first portion 120A (i.e., the common level structure 122) of the conductive layer 120 may be formed as a first conductive stack SK1 after performing the electroplating step, the second portion 120B (i.e., the scan line 124) of the conductive layer 120 may be formed as a second conductive stack SK2 after performing the electroplating step, the third portion 120C (i.e., the floating structure 126) of the conductive layer 120 may be optionally formed as a third conductive stack SK3, and at least one of the first conductive stack SK1, the second conductive stack SK2 and the third conductive stack SK3 may be a multi-layer conductive structure. For instance, in FIG. 7, the first conductive stack SK1, the second conductive stack SK2 and the third conductive stack SK3 may be multi-layer conductive structures, and each of these multi-layer conductive structures may include different conductive materials (e.g., molybdenum, aluminum and copper), but not limited thereto.

Compared with a manufacturing method of an electronic device including conductive layers with single thickness, the manufacturing method of the electronic device 100 of this embodiment does not need to increase the number of the photomasks and the number of the etching processes, such that the manufacturing cost of the electronic device 100 of this embodiment could be controlled and saved. In addition, since the manufacturing method of the electronic device 100 of this embodiment forms the conductive layer 120 with different thicknesses through only one electroplating step, the manufacturing cost of the electronic device 100 of this embodiment could be controlled and saved.

In the present disclosure, the electronic device and the manufacturing method of the electronic device are not limited to the above embodiments. Further embodiments of the present disclosure are described below. For ease of comparison, same components will be labeled with the same symbol in the following. The following descriptions relate the differences between each of the embodiments, and repeated parts will not be redundantly described.

Referring to FIG. 9 to FIG. 13, FIG. 9 to FIG. 13 are schematic diagrams illustrating structures at different stages of manufacturing method of an electronic device according to a second embodiment of the present disclosure, wherein FIG. 9 to FIG. 13 only show the manufacturing method manufacturing the first portion 120A (i.e., the common level structure 122) and the second portion 120B (i.e., the scan line 124) of the electronic device 100. As shown in FIG. 9 to FIG. 13, compared with the first embodiment shown in FIG. 5 to FIG. 8, the manufacturing method of the electronic device 100 of this embodiment manufactures the conductive layer 120 with different thicknesses through the photoresist layer PR with different thicknesses and performing a plurality of electroplating processes in the electroplating step. Details of the manufacturing method of the electronic device 100 of this embodiment are described in the following.

As shown in FIG. 9, the first conductive sub-layer 120_1 belonging to the conductive layer 120 is formed on the substrate 110. For example, in FIG. 9, the first conductive sub-layer 120_1 may be a single-layer structure without patterning (e.g., the first conductive sub-layer 120_1 may include ITO), but not limited thereto.

As shown in FIG. 9, the photoresist layer PR is formed on the first conductive sub-layer 120_1. Then, the photoresist layer PR is patterned by the yellow light manufacturing process and the developing process, wherein the patterned photoresist layer PR has at least two thicknesses. In some embodiments, the photoresist layer PR may be defined into at least three parts through a gray tone mask, and these parts may respectively receive the lights with different light intensities in the yellow light manufacturing process, so as to make the photoresist layer PR have different thicknesses. For instance (as shown in FIG. 9), the photoresist layer PR (e.g., including negative photoresist material) may be defined into a first part PR1, a second part PR2 and a third part (the third part is removed in FIG. 9) through the gray tone mask in the yellow light manufacturing process, wherein the light intensity of the light received by the first part PR1 may be greater than the light intensity of the light received by the second part PR2, the light intensity of the light received by the second part PR2 may be greater than the light intensity of the light received by the third part (e.g., the third part does not receive the light). Therefore, after performing the developing process, the thickness of the first part PR1 is greater than the thickness of the second part PR2, and the third part is removed to expose the first conductive sub-layer 120_1, but not limited thereto. In another case, if the photoresist layer PR includes positive photoresist material, the light intensity of the light received by the first part PR1 is smallest, the light intensity of the light received by the third part is greatest, and the third part of the photoresist layer PR is removed in the developing process. In FIG. 9, the third part of the photoresist layer PR is corresponding to the second portion 120B (i.e., the scan line 124) of the first conductive sub-layer 120_1 of the conductive layer 120 in the direction Z, and the second part PR2 of the photoresist layer PR is corresponding to the first portion 120A (i.e., the common level structure 122) of the first conductive sub-layer 120_1 of the conductive layer 120 in the direction Z.

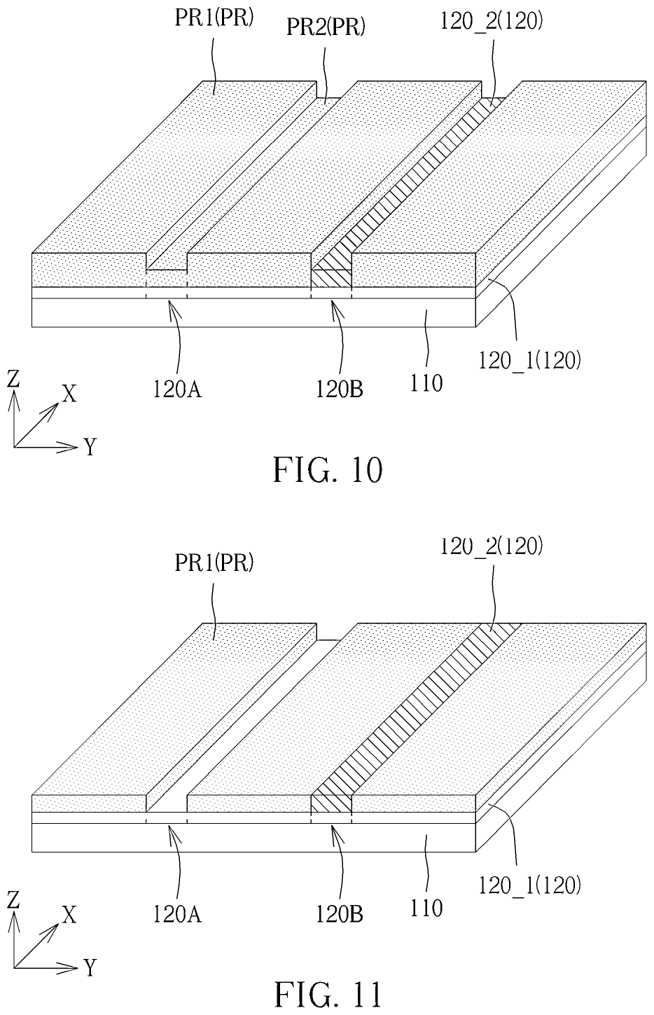

As shown in FIG. 10, a first electroplating process of the electroplating step is performed to energize the first conductive sub-layer 120_1. Since the second portion 120B of the first conductive sub-layer 120_1 is not covered by the photoresist layer PR, the electroplating reaction is performed on the second portion 120B of the first conductive sub-layer 120_1, so as to make the electroplated metal grow on the second portion 120B, thereby making the second conductive sub-layer 120_2 be formed on the second portion 120B of the first conductive sub-layer 120_1. Note that the second conductive sub-layer 120_2 may be a metal layer including any suitable metal (e.g., aluminum or copper).

As shown in FIG. 11, an etching step is performed to thin the photoresist layer PR. In FIG. 11, the first part PR1 of the photoresist layer PR is thinned, and the second part PR2 of the photoresist layer PR is removed to expose the first portion 120A of the first conductive sub-layer 120_1 of the conductive layer 120. For instance, the etching step may include a dry etching process, but not limited thereto.

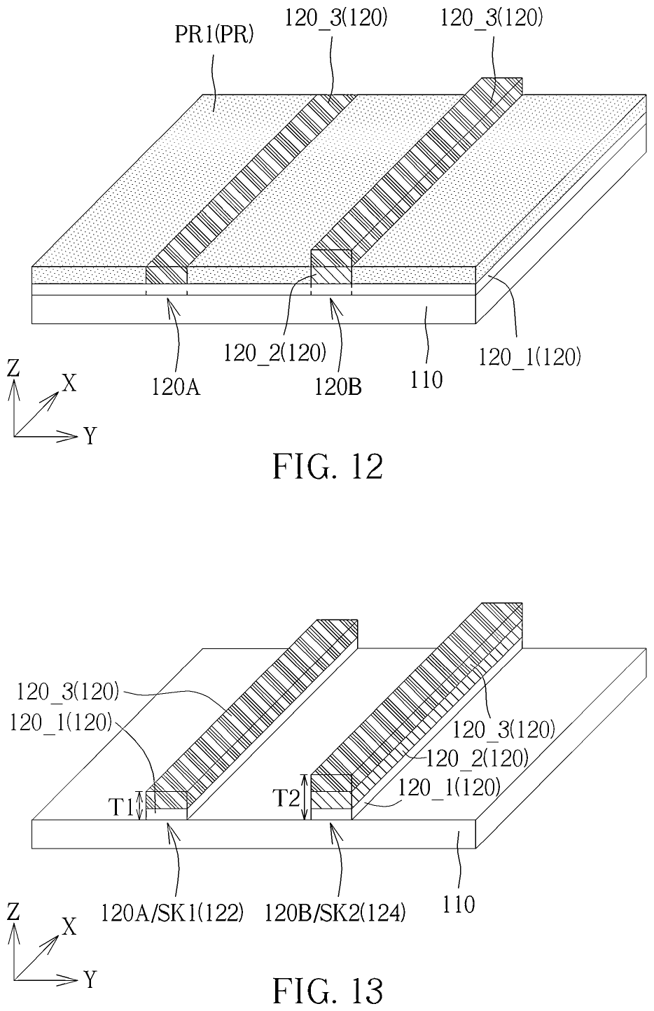

As shown in FIG. 12, a second electroplating process of the electroplating step is performed to energize the first conductive sub-layer 120_1. Since the first portion 120A and the second portion 120B of the first conductive sub-layer 120_1 are not covered by the photoresist layer PR, the electroplating reaction is performed on the first portion 120A and the second portion 120B of the first conductive sub-layer 120_1, so as to make the electroplated metal grow on the first portion 120A and the second portion 120B, thereby making a third conductive sub-layer 120 3 be formed on the first portion 120A and the second portion 120B. Note that the third conductive sub-layer 120 3 may be a metal layer including any suitable metal (e.g., aluminum or copper).

As shown in FIG. 13, the photoresist layer PR is removed by a photoresist removing step. For instance, the photoresist removing step may include a wet etching process, but not limited thereto.

As shown in FIG. 13, a patterning step is performed to pattern the first conductive sub-layer 120_1. For instance, the patterning step may be another etching step to etch a part of the first conductive sub-layer 120_1 which is not covered by the second conductive sub-layer 120_2 and/or the third conductive sub-layer 120 3. For instance, since the material of the first conductive sub-layer 120_1 is different from the material of the second conductive sub-layer 120_2 and the material of the third conductive sub-layer 120 3, this etching step may use a solvent that only etches the material of the first conductive sub-layer 120_1, but not limited thereto.

According to above, in the electroplating step, the first portion 120A (i.e., the common level structure 122) undergoes a first number of electroplating process to form a first conductive stack SK1, the second portion 120B (i.e., the scan line 124) undergoes a second number of electroplating process to form a second conductive stack SK2, and the first number is different from the second number. In the embodiment shown in FIG. 9 to FIG. 13, the second number is greater than the first number, such that the second thickness T2 of the second portion 120B (i.e., the scan line 124) is greater than the first thickness T1 of the first portion 120A (i.e., the common level structure 122). In FIG. 13, the first conductive stack SK1 of the first portion 120A (i.e., the common level structure 122) of the conductive layer 120 may include the first conductive sub-layer 120_1 and the third conductive sub-layer 120 3 to be a multi-layer conductive structure, the second conductive stack SK2 of the second portion 120B (i.e., the scan line 124) of the conductive layer 120 may include the first conductive sub-layer 120_1, the second conductive sub-layer 120_2 and the third conductive sub-layer 120 3 to be a multi-layer conductive structure, and each of these multi-layer conductive structures may include different conductive materials (e.g., ITO, molybdenum, aluminum and copper), but not limited thereto.

Compared with a manufacturing method of an electronic device including conductive layers with single thickness, the manufacturing method of the electronic device 100 of this embodiment does not need to increase the number of the photomasks, such that the manufacturing cost of the electronic device 100 of this embodiment could be controlled and saved.

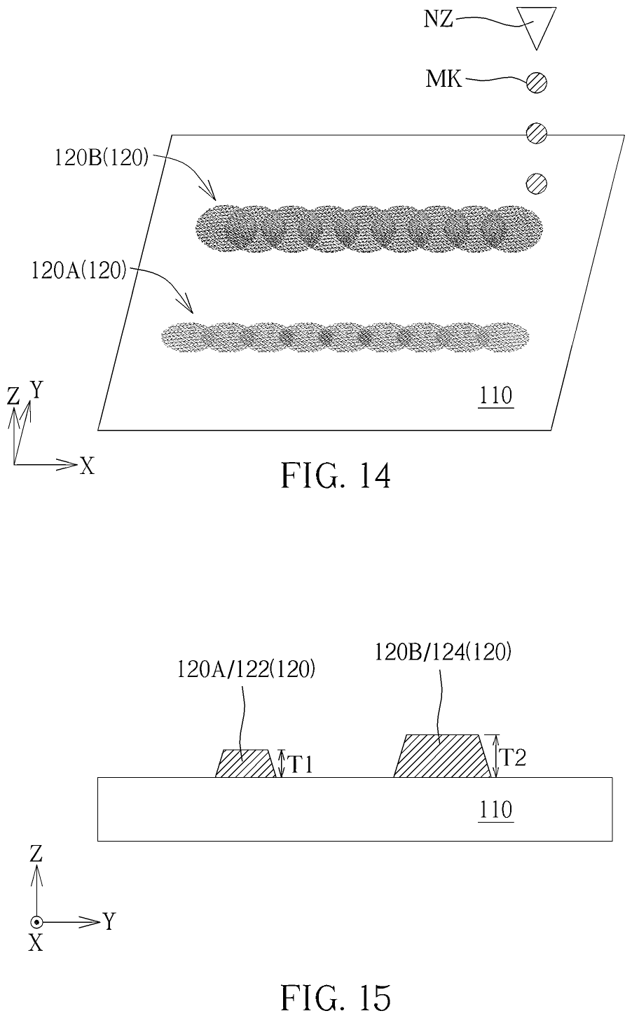

Referring to FIG. 14 to FIG. 15, FIG. 14 to FIG. 15 are schematic diagrams illustrating structures at different stages of a manufacturing method of an electronic device according to a third embodiment of the present disclosure, wherein FIG. 14 to FIG. 15 only show the manufacturing method manufacturing the first portion 120A (i.e., the common level structure 122) and the second portion 120B (i.e., the scan line 124) of the electronic device 100. In FIG. 14 and FIG. 15, the manufacturing method of the electronic device 100 of this embodiment forms the conductive layer 120 with different thicknesses through an inkjet printing step.

As shown in FIG. 14 and FIG. 15, the substrate 110 is provided, and then, the inkjet printing step is performed. In the inkjet printing step, a nozzle NZ sprays the metallic ink MK on the corresponding position of the substrate 110 according to the required pattern of the conductive layer 120 (as shown in FIG. 14). Next, a curing process (e.g., heating or light irradiation) is performed to cure the metallic ink MK for forming the conductive layer 120 including the grid structure MS having a plurality of grid units 120M (as shown in FIG. 15). In the present disclosure, the metallic ink MK may include any suitable metal material. For instance, the metallic ink MK may include copper, silver (Ag), gold (Au), other suitable metal material or a combination thereof.

As shown in FIG. 14 and FIG. 15, in the inkjet printing step, the thicknesses of each position of the conductive layer 120 may be controlled by controlling a metallic amount of the metallic ink MK received by an unit area of different regions, so as to form the first portion 120A (i.e., the common level structure 122), the second portion 120B (i.e., the scan line 124) and the third portion 120C (i.e., the floating structure 126) which have different thicknesses respectively, wherein the thickness would be thinner when the metallic amount received by the unit area is smaller. In other words, a first region may be corresponding to the first portion 120A (i.e., the first portion 120A is situated in the first region), a second region may be corresponding to the second portion 120B (i.e., the second portion 120B is situated in the second region), a third region may be corresponding to the third portion 120C (i.e., the third portion 120C is situated in the third region), and a metallic amount of the metallic ink MK received by an unit area of the first region, a metallic amount of the metallic ink MK received by an unit area of the second region and a metallic amount of the metallic ink MK received by an unit area of the third region may be different. For instance, the first portion 120A (i.e., the common level structure 122), the second portion 120B (i.e., the scan line 124) and the third portion 120C (i.e., the floating structure 126) of the conductive layer 120 may be formed by spraying the metallic ink MK with different injecting amounts and/or different concentrations through the nozzle NZ.

Compared with a manufacturing method of an electronic device including conductive layers with single thickness, the manufacturing method of the electronic device 100 of this embodiment does not need to increase the number of the photomasks and the number of the forming processes (e.g., the deposition processes) of the films, such that the manufacturing cost of the electronic device 100 of this embodiment could be controlled and saved.

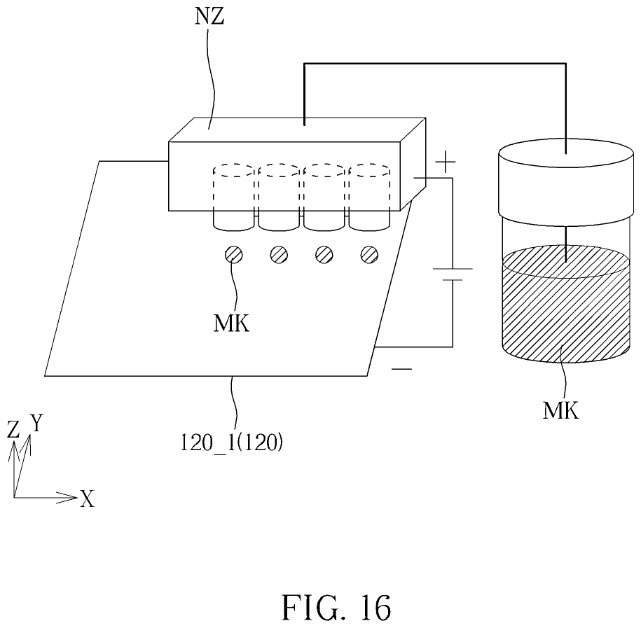

Referring to FIG. 16 to FIG. 18, FIG. 16 to FIG. 18 are schematic diagrams illustrating structures at different stages of a manufacturing method of an electronic device according to a fourth embodiment of the present disclosure, wherein FIG. 16 to FIG. 18 only show the manufacturing method manufacturing the first portion 120A (i.e., the common level structure 122) and the second portion 120B (i.e., the scan line 124) of the electronic device 100. As shown in

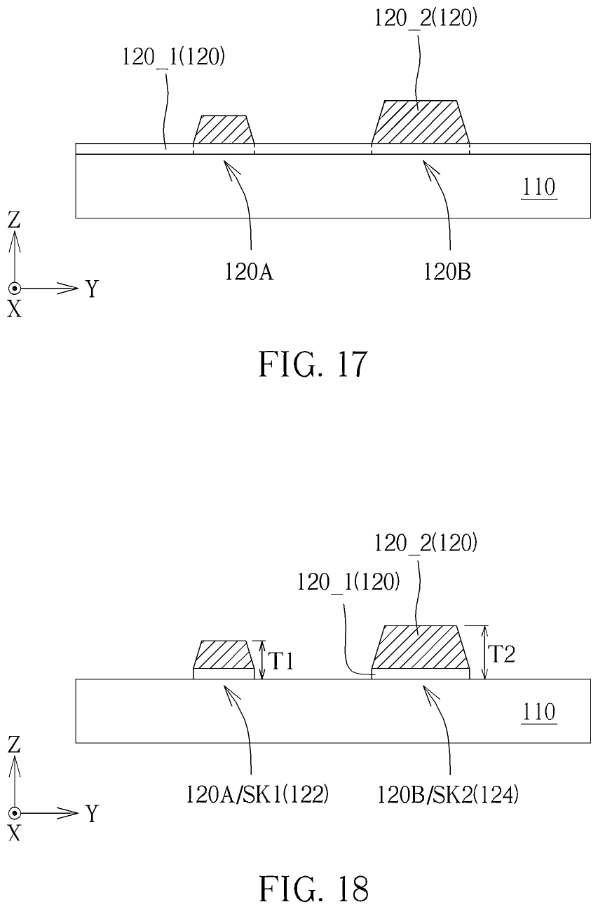

FIG. 16 to FIG. 18, compared with the third embodiment shown in FIG. 14 to FIG. 15, the inkjet printing step of the manufacturing method of the electronic 100 of this embodiment is an electrohydrodynamic printing step. As shown in FIG. 16 and FIG. 17, the first conductive sub-layer 120_1 belonging to the conductive layer 120 is formed on the substrate 110. For example, in FIG. 16 and FIG. 17, the first conductive sub-layer 120_1 may be a single-layer structure (e.g., the first conductive sub-layer 120_1 may include ITO), but not limited thereto.

As shown in FIG. 16 and FIG. 17, the inkjet printing step (i.e., the electrohydrodynamic printing step) is performed, wherein the first conductive sub-layer 120_1 and the metallic ink MK are energized (e.g., the voltages are applied on them), and the nozzle NZ sprays the metallic ink MK on the corresponding position of the first conductive sub-layer 120_1 according to the required pattern of the conductive layer 120. Next, the curing process (e.g., heating or light irradiation) is performed to cure the metallic ink MK for forming the second conductive sub-layer 120_2. In FIG. 16 and FIG. 17, in the inkjet printing step, the thicknesses of each position of the second conductive sub-layer 120_2 may be controlled by controlling the metallic amount of the metallic ink MK received by the unit area of different regions, so as to form the first portion 120A (i.e., the common level structure 122), the second portion 120B (i.e., the scan line 124) and the third portion 120C (i.e., the floating structure 126) which have different thicknesses respectively, wherein the thickness would be thinner when the metallic amount received by the unit area is smaller.

As shown in FIG. 18, a patterning step is performed to pattern the first conductive sub-layer 120_1. For instance, the patterning step may be an etching step to etch a part of the first conductive sub-layer 120_1 which is not covered by the second conductive sub-layer 120_2. For instance, since the material of the first conductive sub-layer 120_1 is different from the material of the second conductive sub-layer 120_2, this etching step may use a solvent that only etches the material of the first conductive sub-layer 120_1, but not limited thereto. In FIG. 18, in the first portion 120A (i.e., the common level structure 122) and the second portion 120B (i.e., the scan line 124) of the conductive layer 120, the first conductive stack SK1 of the first portion 120A (i.e., the common level structure 122) may include the first conductive sub-layer 120_1 and the thinner second conductive sub-layer 120_2, and the second conductive stack SK2 of the second portion 120B (i.e., the scan line 124) may include the first conductive sub-layer 120_1 and the thicker second conductive sub-layer 120_2.

Since the electrohydrodynamic printing step is used in the formation of the conductive layer 120, the formed structure (e.g., the conductive trace) may have smaller width and higher precision.

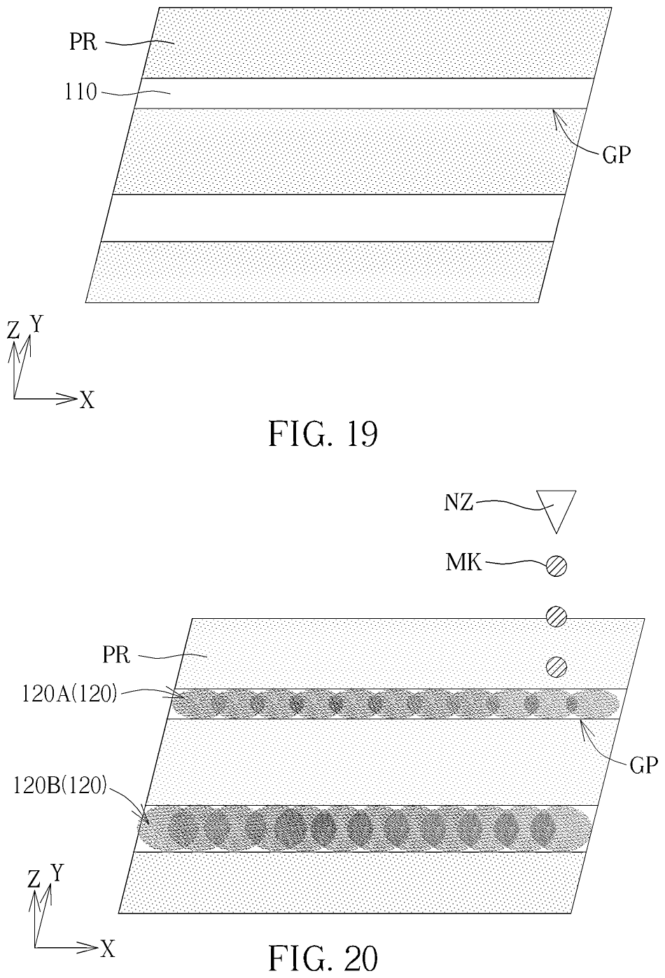

Referring to FIG. 19 to FIG. 23, FIG. 19 to FIG. 23 are schematic diagrams illustrating structures at different stages of a manufacturing method of an electronic device according to a fifth embodiment of the present disclosure, wherein FIG. 19 to FIG. 23 only show the manufacturing method manufacturing the first portion 120A (i.e., the common level structure 122) and the second portion 120B (i.e., the scan line 124) of the electronic device 100. As shown in FIG. 19 to FIG. 23, compared with the third embodiment shown in FIG. 14 to FIG. 15, a photoresist layer PR having a plurality of gaps GP is formed on the substrate 110 before performing the inkjet printing step. In the inkjet printing step, the nozzle NZ sprays the metallic ink MK in the gaps GP of the photoresist layer PR, such that the first portion 120A (i.e., the common level structure 122), the second portion 120B (i.e., the scan line 124) and the third portion 120C (i.e., the floating structure 126) which have different thicknesses respectively are formed in different gaps GP of the photoresist layer PR respectively.

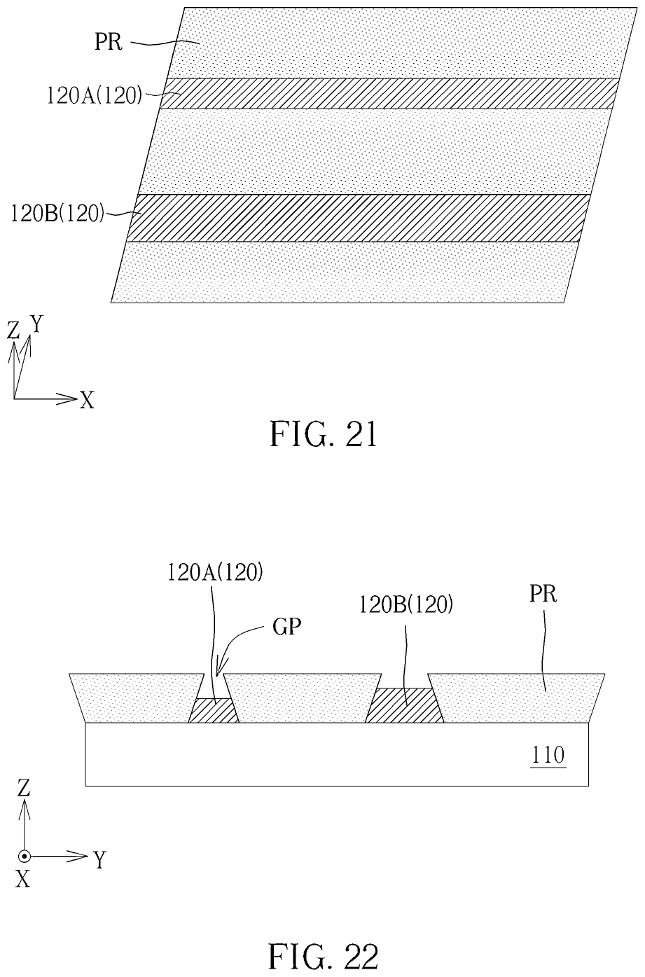

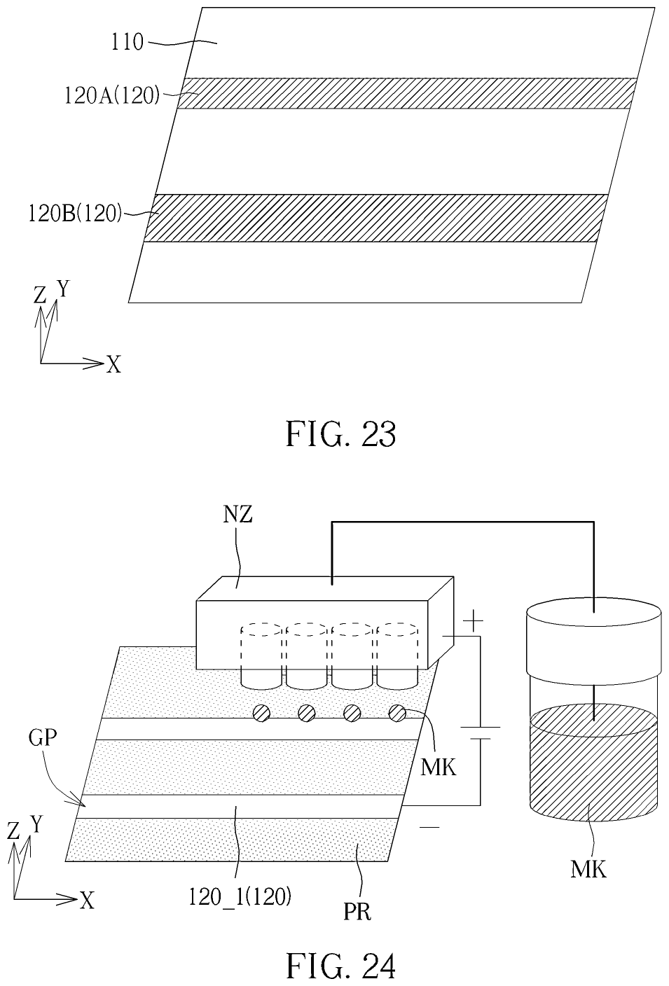

In detail, as shown in FIG. 19, the photoresist layer PR is patterned according to the required pattern of the conductive layer 120, such that the gap GP is corresponding to the region where the conductive layer 120 is to be formed. As shown in FIGS. 20 to 22, in the inkjet printing step, the nozzle NZ correspondingly control the metallic amount of the metallic ink MK sprayed in the unit area according to the thicknesses of each position of the conductive layer 120 (as shown in FIG. 20). Then, the curing process (e.g., heating or light irradiation) is performed to cure the metallic ink MK for forming the conductive layer 120 (as shown in FIG. 21 and FIG. 22). As shown in FIG. 23, the photoresist layer PR is removed by a photoresist removing step. Due to the patterned photoresist layer PR, the pattern of the conductive layer 120 of this embodiment may be more precise than the pattern of the conductive layer 120 of the third embodiment shown in FIG. 14.

In some embodiments, as shown in FIG. 22, after patterning the photoresist layer PR to form the gaps GP, a size of the top surface of the photoresist layer PR is greater than a size of the bottom surface of the photoresist layer PR in cross-sectional view (i.e., a cross-sectional profile of the photoresist layer PR is a trapezoid having a longer topline larger and a shorter baseline), so as to make the conductive layer 120 have a suitable cross-sectional profile (i.e., a size of the top surface of the conductive layer 120 is less than a size of the bottom surface of the conductive layer 120, such that the cross-sectional profile of the conductive layer 120 is a trapezoid having a shorter topline larger and a longer baseline), thereby increasing the success rate of subsequent processes (e.g., the formation of the subsequent film(s)) and increasing the yield rate of the electronic device 100. Furthermore, because of the design of the cross-sectional profile of the photoresist layer PR, the photoresist layer PR may be easily removed, so as to increase the yield rate of the electronic device 100.

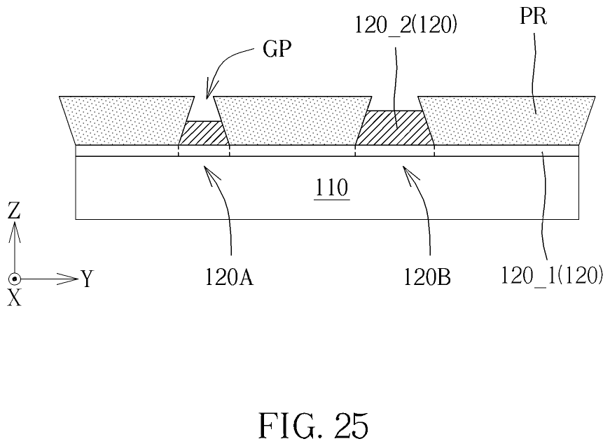

Referring to FIG. 24 to FIG. 25, FIG. 24 to FIG. 25 are schematic diagrams illustrating structures at different stages of a manufacturing method of an electronic device according to a sixth embodiment of the present disclosure, wherein FIG. 24 to FIG. 25 only show the manufacturing method manufacturing the first portion 120A (i.e., the common level structure 122) and the second portion 120B (i.e., the scan line 124) of the electronic device 100. As shown in FIG. 24 to FIG. 25, compared with the fifth embodiment shown in FIG. 19 to FIG. 23, the inkjet printing step of the manufacturing method of the electronic device 100 of this embodiment is an electrohydrodynamic printing step. Therefore, as shown in FIG. 24 to FIG. 25, before forming the photoresist layer PR, the first conductive sub-layer 120_1 belonging to the conductive layer 120 is formed on the substrate 110. For instance, in FIG. 24 to FIG. 25, the first conductive sub-layer 120_1 may be a single-layer structure (e.g., the first conductive sub-layer 120_1 may include ITO), but not limited thereto.

As shown in FIG. 24 to FIG. 25, the inkjet printing step (i.e., the electrohydrodynamic printing step) is performed, wherein the first conductive sub-layer 120_1 and the metallic ink MK are energized (e.g., the voltages are applied on them), and the nozzle NZ sprays the metallic ink MK in the gaps GP of the photoresist layer PR, such that the first portion 120A (i.e., the common level structure 122), the second portion 120B (i.e., the scan line 124) and the third portion 120C (i.e., the floating structure 126) which have different thicknesses respectively are formed in different gaps GP of the photoresist layer PR respectively. Then, the curing process (e.g., heating or light irradiation) is performed to cure the metallic ink MK for forming the second conductive sub-layer 120_2. In FIG. 24 to FIG. 25, in the inkjet printing step, the thicknesses of each position of the second conductive sub-layer 120_2 may be controlled by controlling the metallic amount of the metallic ink MK received by the unit area of different regions, so as to form the first portion 120A (i.e., the common level structure 122), the second portion 120B (i.e., the scan line 124) and the third portion 120C (i.e., the floating structure 126) which have different thicknesses respectively, wherein the thickness would be thinner when the metallic amount received by the unit area is smaller.

Next, the photoresist layer PR is removed by the photoresist removing step (e.g., FIG. 17), and then, a patterning step is performed to pattern the first conductive sub-layer 120_1 (e.g., FIG. 18). For example, the patterning step may be an etching step to etch a part of the first conductive sub-layer 120_1 which is not covered by the second conductive sub-layer 120_2. According to FIG. 18, in the first portion 120A (i.e., the common level structure 122) and the second portion 120B (i.e., the scan line 124) of the conductive layer 120, the first conductive stack SK1 of the first portion 120A (i.e., the common level structure 122) may include the first conductive sub-layer 120_1 and the thinner second conductive sub-layer 120_2, and the second conductive stack SK2 of the second portion 120B (i.e., the scan line 124) may include the first conductive sub-layer 120_1 and the thicker second conductive sub-layer 120_2. Due to the patterned photoresist layer PR, the pattern of the conductive layer 120 of this embodiment may be more precise than the pattern of the conductive layer 120 of the fourth embodiment shown in FIG. 16.

In summary, since the structures in the conductive layer of the electronic device of the present disclosure have different thicknesses, the display quality and the yield rate of the electronic device are enhanced. Furthermore, according to the manufacturing method of the electronic device of the present disclosure, the electronic device including the conductive layer having different thicknesses could be manufactured in the condition that the manufacturing cost could be controlled and saved.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate;
disposing a conductive layer on the substrate;
performing a patterning step to pattern the conductive layer, such that a grid structure having a plurality of grid units is formed in the conductive layer, and the conductive layer which is patterned comprises a first portion and a second portion at least; and
performing an electroplating step to electroplate at least one of the first portion and the second portion, such that a thickness of the first portion is different from a thickness of the second portion after performing the electroplating step.

2. The manufacturing method according to claim 1, wherein the patterning step is an etching step.

3. The manufacturing method according to claim 1, wherein in the electroplating step, the first portion is coupled to a first electric current, the second portion is coupled to a second electric current, and an electric current density of the first electric current is different from an electric current density of the second electric current.

4. The manufacturing method according to claim 3, wherein the first electric current and the second electric current are supplied simultaneously in the electroplating step.

5. The manufacturing method according to claim 1, wherein in the electroplating step, the first portion undergoes a first number of electroplating process to form a first conductive stack, the second portion undergoes a second number of electroplating process to form a second conductive stack, and the first number is different from the second number.

6. The manufacturing method according to claim 5, wherein at least one of the first conductive stack and the second conductive stack has a multi-layer conductive structure, and the multi-layer conductive structure comprises different conductive materials.

7. The manufacturing method according to claim 5, wherein the patterning step is performed after the electroplating step is performed.

8. The manufacturing method according to claim 1, wherein the electronic device comprises a plurality of display units, one of the plurality of display units is corresponding to one of the plurality of grid units, the first portion of the conductive layer comprises at least one edge of one of the plurality of grid units, and the second portion of the conductive layer is corresponding to at least two of the plurality of grid units.

9. The manufacturing method according to claim 1, wherein the conductive layer is a metal layer.

10. The manufacturing method according to claim 1, wherein the first portion of the conductive layer is a common level structure, and the second portion of the conductive layer is a scan line.

11. The manufacturing method according to claim 10, wherein the thickness of the first portion of the conductive layer is less than the thickness of the second portion of the conductive layer.

12. The manufacturing method according to claim 1, wherein the conductive layer further comprises a third portion, the thickness of the first portion and the thickness of the second portion are greater than a thickness of the third portion after performing the electroplating step.

13. The manufacturing method according to claim 12, wherein the third portion of the conductive layer is a floating structure, and the third portion is not energized during the electroplating step.

14. A manufacturing method of an electronic device, comprising:
providing a substrate; and
performing an inkjet printing step to form a conductive layer on the substrate;
wherein the conductive layer comprises a grid structure having a plurality of grid units, the conductive layer comprises a first portion and a second portion at least, and a thickness of the first portion is different from a thickness of the second portion.

15. The manufacturing method according to claim 14, wherein a first region is corresponding to the first portion, a second region is corresponding to the second portion, and a metallic amount of metallic ink received by an unit area of the first region is different from a metallic amount of metallic ink received by an unit area of the second region in the inkjet printing step.

16. The manufacturing method according to claim 14, further comprising:
forming a photoresist layer on the substrate before performing the inkjet printing step, wherein the photoresist layer has a plurality of gaps;
wherein the first portion and the second portion of the conductive layer formed by the inkjet printing step are formed in the plurality of gaps of the photoresist layer.

17. The manufacturing method according to claim 14, wherein the inkjet printing step is an electrohydrodynamic printing step.

18. The manufacturing method according to claim 14, wherein the first portion of the conductive layer is a common level structure, and the second portion of the conductive layer is a scan line.

19. The manufacturing method according to claim 18, wherein the thickness of the first portion of the conductive layer is less than the thickness of the second portion of the conductive layer.

20. The manufacturing method according to claim 14, wherein the conductive layer further comprises a third portion, the thickness of the first portion and the thickness of the second portion are greater than a thickness of the third portion after performing the inkjet printing step.
